(19) United States
(12) Patent Application Publication
(10) Pub. No.: US 2025/0280715 A1
(43) Pub. Date: Sep. 4, 2025

(54) DISPLAY DEVICE

(71) Applicant: Samsung Display Co., LTD., Yongin-si, Gyeonggi-do (KR)

(72) Inventors: Mi Hyang SHEEN, Yongin-si, Gyeonggi-do (KR); Ki Seong SEO, Yongin-si, Gyeonggi-do (KR); Jae Yune CHANG, Yongin-si, Gyeonggi-do (KR)

(73) Assignee: Samsung Display Co., LTD., Yongin-si, Gyeonggi-do (KR)

(21) Appl. No.: 18/798,179

(22) Filed: Aug. 8, 2024

(30) Foreign Application Priority Data
Sep. 4, 2023 (KR) 10-2023-0117125

(51) Int. Cl. H10K 59/80; H01L 25/075; H10H 29/37; H10H 29/80; H10H 29/85; H10H 29/855; H10H 29/856; H10K 59/12; H10K 59/38

(52) U.S. Cl. CPC H10K 59/879; H01L 25/0753; H10H 29/37; H10H 29/8325; H10H 29/8517; H10H 29/855; H10H 29/856; H10K 59/1201; H10K 59/38; H10K 59/878

(57) ABSTRACT

A display device includes a pixel electrode disposed on a substrate, light emitting elements disposed on the pixel electrode, the light emitting elements including a first semiconductor layer, an active layer, a second semiconductor layer, and a third semiconductor layer, a first via layer disposed on the substrate, and having a higher height than a height of the active layer and having a lower height than a height of the third semiconductor layer and a common electrode disposed on the first via layer and surrounding the side surfaces of the light emitting elements, the light emitting elements include two or more heterogeneous insulating layers having different refractive indices, and the heterogeneous insulating layers surround top and side surfaces of the first semiconductor layer and side surfaces of the first semiconductor layer and further surround at least a portion of a side surface of the second semiconductor layer.

### CROSS-REFERENCE TO RELATED APPLICATION(S)

This application claims priority to and benefits of Korean Patent Application No. 10-2023-0117125 under 35 U.S.C. § 119 filed on Sep. 4, 2023, in the Korean Intellectual Property Office, the entire contents of which are incorporated herein by reference.

### BACKGROUND

### 1. Technical Field

The disclosure relates to a display device.

### 2. Description of the Related Art

Display devices are becoming increasingly important with the development of multimedia. In response to this, various types of display devices, such as organic light emitting displays (OLED) and liquid crystal displays (LCD), are being used.

A device for displaying an image of a display device may include a display panel such as an organic light emitting display panel or a liquid crystal display panel. Among them, the light emitting display panel may include a light emitting element. For example, light emitting diodes (LED) include organic light emitting diodes (OLED) that utilize organic materials as light emitting materials, inorganic light emitting diodes that utilize inorganic materials as light emitting materials, and the like.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects and features of embodiments of the disclosure provide a display device that may improve the light emission efficiency of a light emitting element by forming a common electrode in direct contact with a second semiconductor layer and a heterogeneous insulating layer to surround the light emitting element.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an embodiment, a display device may include a pixel electrode disposed on a substrate; light emitting elements disposed on the pixel electrode, the light emitting elements including a first semiconductor layer, an active layer, a second semiconductor layer, and a third semiconductor layer; a first via layer disposed on the substrate, and having a higher height than a height of the active layer and having a lower height than a height of the third semiconductor layer and a common electrode disposed on the first via layer and surrounding side surfaces of the light emitting elements, wherein the light emitting elements include two or more heterogeneous insulating layers having different refractive indices, and the heterogeneous insulating layers surround top and side surfaces of the first semiconductor layer and further surround at least a portion of a side surface of the second semiconductor layer.

The heterogeneous insulating layers may include a first insulating layer having a first refractive index and a second insulating layer having a second refractive index and disposed farther from the active layer than the first insulating layer, wherein the first refractive index is less than the second refractive index.

A difference between the first refractive index and the second refractive index may be about 0.4 or more.

A bandgap of the heterogeneous insulating layers may be about 3.4 or more.

A height of the second semiconductor layer surrounded by the common electrode may be about 20 nm or more.

A height of the heterogeneous insulating layers and a height of the first via layer may be the same.

A height of the common electrode and a height of the second via layer may be equal.

The heterogeneous insulating layers may have an opening exposing a surface of the first semiconductor layer, wherein the light emitting elements further include a connection electrode disposed on a surface of the first semiconductor layer exposed by the opening.

The third semiconductor layer may have a substantially concave-convex structure.

The common electrode may include a high reflectivity conductive metal.

The display device may further comprise a capping layer covering a top surface of the third semiconductor layer and a top surface of the second via layer, wherein the capping layer directly contacts the top surface of the third semiconductor layer.

The display device may further comprise a reflective layer surrounding a side of the light emitting elements on the common electrode.

The display device may further comprise a bank layer disposed on the substrate and dividing a light emitting area and a non-emitting area.

The display device may further comprise partition walls disposed on the common electrode and overlapping the bank layer; a wavelength conversion layer disposed between the partition walls and a color filter layer disposed on the wavelength conversion layer.

A display device may include a pixel electrode disposed on a substrate; light emitting elements disposed on the pixel electrode, the light emitting elements including a first semiconductor layer, an active layer, and a second semiconductor layer' a first via layer disposed on the substrate and disposed lower than a height of the second semiconductor layer and a common electrode disposed on the first via layer and surrounding a side of the second semiconductor layer of the light emitting elements, wherein the light emitting elements include two or more heterogeneous insulating layers having different refractive indices, and the heterogeneous insulating layers surround top and side surfaces of the first semiconductor layer and side surfaces of the first semiconductor layer and further surround at least a portion of a side surface of the second semiconductor layer.

The heterogeneous insulating layers may include a first insulating layer having a first refractive index and a second insulating layer having a second refractive index and disposed farther from the active layer than the first insulating layer, wherein the first refractive index is less than the second refractive index.

A difference between the first refractive index and the second refractive index may be about 0.4 or more.

A bandgap of the heterogeneous insulating layers may be about 3.4 or more.

A height of the heterogeneous insulating layers and a height of the first via layer may be the same and a height of the common electrode and a height of the second via layer may be equal.

The heterogeneous insulating layers may have an opening exposing a surface of the first semiconductor layer, wherein the light emitting elements may further include a connection electrode disposed on a surface of the first semiconductor layer exposed by the opening.

According to a display device according to embodiments may include a common electrode surrounding a side of the light emitting element and a heterogeneous insulating layer, thereby reflecting light emitted from the light emitting element to the side upward. Accordingly, the light emission efficiency of the light emitting element may be improved.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to one embodiment.

FIGS. 2 and 3 are plan views illustrating a display device according to one embodiment.

FIG. 4 is a schematic diagram of an equivalent circuit illustrating a first sub-pixel of a display panel according to one embodiment.

FIG. 5 is a schematic diagram of an equivalent circuit illustrating a first sub-pixel of a display panel according to an embodiment.

FIG. 6 is a schematic cross-sectional view schematically illustrating a display device according to one embodiment.

FIG. 7 is a schematic cross-sectional view illustrating a pixel electrode and a light emitting element according to one embodiment.

FIG. 8 is an enlarged view of area P in FIG. 7.

FIG. 9 is a schematic cross-sectional view schematically illustrating a display device according to an embodiment.

FIG. 10 is a schematic cross-sectional view illustrating a pixel electrode and a light emitting element according to the embodiment of FIG. 9.

FIG. 11 is a schematic cross-sectional view schematically illustrating a display device according to an embodiment.

FIG. 12 is a schematic cross-sectional view illustrating a pixel electrode and a light emitting element according to the embodiment of FIG. 11.

FIG. 13 is a graph illustrating resistance values according to carrier concentration in a light emitting element according to one embodiment.

FIGS. 14 to 26 are diagrams for illustrating a method of manufacturing a display device according to one embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements disposed therebetween.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described in detail with reference to the accompanying drawings.

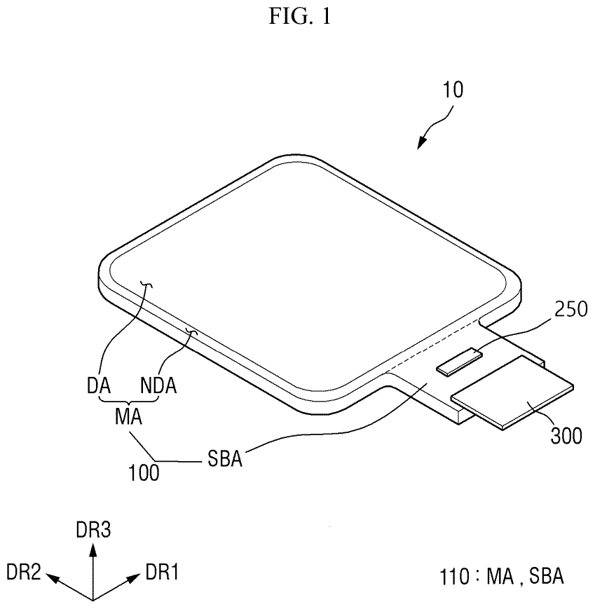

FIG. 1 is a schematic perspective view illustrating a display device according to one embodiment.

Referring to FIG. 1, a display device 10 is a device for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and the internet of things (IOT).

The display device 10 may be a light emitting display device, such as an organic light emitting display device utilizing an organic light emitting diode, a quantum dot light emitting display device including a quantum dot light emitting layer, an inorganic light emitting display device including an inorganic semiconductor, and a miniaturized light emitting display device utilizing a micro or nano light emitting diode (micro LED or nano LED). Hereinafter, the description focuses on the fact that the display device 10 is a micro-light emitting display device, but the disclosure is not limited thereto. On the other hand, the subminiature light emitting diode is described herein as a micro light emitting diode for convenience of explanation.

The display device 10 may include a display panel 100, a display driving circuit 250, and a circuit board 300.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a selectable curvature or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, or rolled.

The display panel 100 may include a main area MA and a sub-area SBA.

The main area MA may include a display area DA that displays an image and a non-display area NDA that is a peripheral area of the display area DA.

The sub-area SBA may protrude from one side (or a side) of the main area MA in the second direction DR2. Although FIG. 1 illustrates the sub-area SBA being unfolded, the sub-area SBA may be bent, and in this case, may be disposed on the bottom surface of the display panel 100. In case that the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. For example, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board, a printed circuit board, or a chip on film.

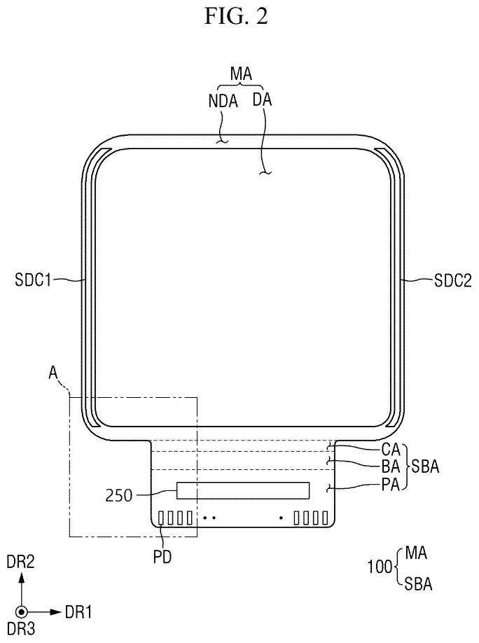

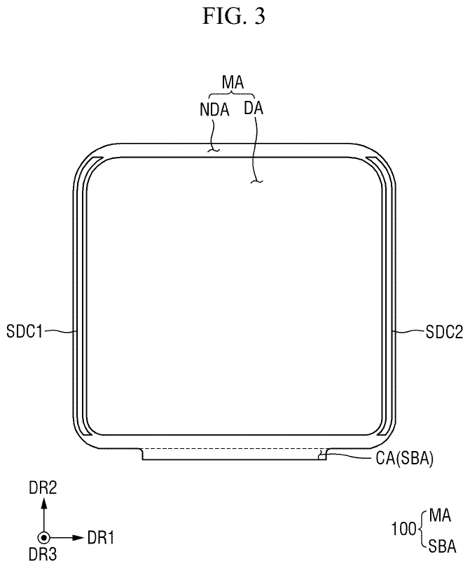

FIGS. 2 and 3 are plan views illustrating a display device according to one embodiment. FIG. 2 illustrates that the sub-area SBA is unfolded without being bent. FIG. 3 illustrates that the sub-area SBA is bent.

Referring to FIGS. 2 and 3, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The non-display area NDA may be placed adjacent to the display area DA. The non-display area NDA may be an area outside the display area DA. The non-display area NDA may be arranged (or disposed) to surround the display area DA. The non-display area NDA may be an edge area of the display panel 100.

A first scan driving unit (or first scan driver) SDC1 and a second scan driving unit (or second scan driver) SDC2 may be disposed in the non-display area NDA. The first scan driving unit SDC1 is disposed on one side (or a side) (for example, the left side) of the display panel 100, and the second scan driving unit SDC2 is disposed on the other side (for example, the right side) of the display panel 100. However, it is not limited to. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side (or a side) of the main area MA in the second direction DR2. The length of the sub-area SBA in the second direction DR2 may be smaller than the length of the main area MA in the second direction DR2. The length of the first direction DR1 of the sub-area SBA is smaller than the length of the first direction DR1 of the main area MA or may be substantially equal to the length of the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side (or a side) of the main area MA in the second direction DR2. One side (or a side) of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side (or a side) of the pad area PA may be in contact with the bending area BA.

The bending area BA is a bent area. In case that the bending area BA is bent, the pad area PA may be disposed below the connection area CA and below the main area MA. The bending area BA may be disposed between the connection area CA and the pad area PA. One side (or a side) of the bending area BA may be in contact with the connection area CA, and the other side of the bending area BA may be in contact with the pad area PA.

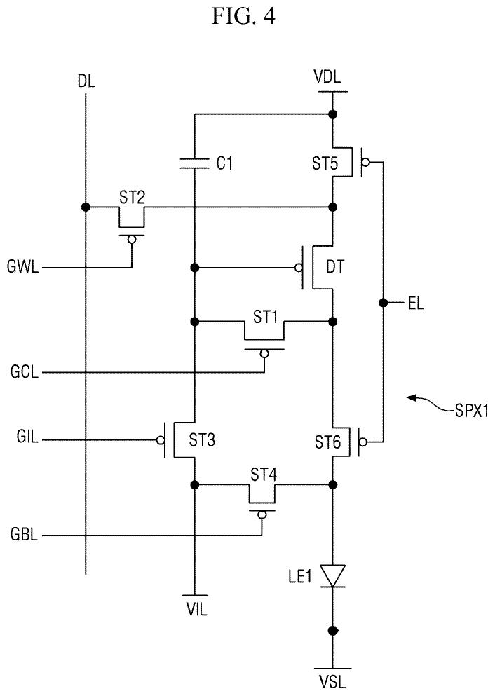

FIG. 4 is a schematic diagram of an equivalent circuit illustrating a first sub-pixel of a display panel according to one embodiment.

Referring to FIG. 4, the first sub-pixel SPX1 according to one embodiment may be connected to scan lines GWL, GIL, GCL, and GBL, light emitting lines EL, and data lines DL. For example, the first sub-pixel SPX1 may be connected to a write scan line GWL, an initialization scan line GIL, the control scan line GCL, the bias scan line GBL, a light emitting line EL, and the data line DL.

The first sub-pixel SPX1 according to one embodiment may include a driving transistor DT, switch elements, a capacitor C1, and a first light emitting element LE1. The switch elements include first to sixth transistors ST1, ST2, ST3, ST4, ST5, and ST6.

The driving transistor DT may include a gate electrode, a first electrode, and a second electrode. The driving transistor DT controls the drain-source current (Ids, hereinafter referred to as “driving current”) flowing between the first electrode and the second electrode according to the data voltage applied to the gate electrode.

The first light emitting element LE1 may be an organic light emitting diode including an anode electrode (or pixel electrode), a cathode electrode (or common electrode), and an organic light emitting layer disposed between the anode electrode and the cathode electrode. By way of example, the first light emitting element LE1 may be an inorganic light emitting element including the anode electrode, the cathode electrode, and the inorganic semiconductor disposed between the anode electrode and the cathode electrode. By way of example, the first light emitting element LE1 may be a quantum dot light emitting layer including the anode electrode, the cathode electrode, and a quantum dot light emitting layer disposed between the anode electrode and the cathode electrode. By way of example, the first light emitting element LE1 may be a micro light emitting diode. Hereinafter, the description focuses on the fact that the light emitting element LE is a micro light emitting diode for convenience of explanation.

The first light emitting element LE1 emits light according to the driving current Ids. The amount of light emitted from the first light emitting element LE1 may be proportional to the driving current Ids. An anode electrode of the first light emitting element LE1 may be connected to the first electrode of the fourth transistor ST4 and the second electrode of the sixth transistor ST6, a cathode electrode may be connected to the second power supply line VSL to which the second power supply voltage is applied.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Since the first to sixth transistors ST1, ST2, ST3, ST4, ST5, and ST6 are formed as p-type MOSFET, they may be turned on in case that a scan signal of the gate low voltage and an emission signal are applied to the control scan line GCL, the initialization scan line GIL, the write scan line GWL, the bias scan line GBL, and the light emitting line EL, respectively. One electrode of the third transistor ST3 and one electrode of the fourth transistor ST4 may be connected to an initialization voltage line VIL.

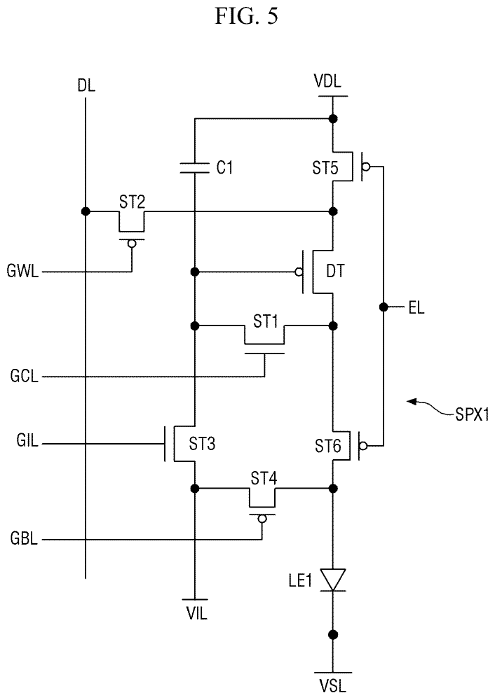

FIG. 5 is a schematic diagram of an equivalent circuit illustrating a first sub-pixel of a display panel according to an embodiment.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Since the first transistor ST1 and the third transistor ST3 are formed as n-type MOSFET, the first transistor ST1 may be turned on in case that a control scan signal with a gate high voltage is applied to the control scan line GCL, and the third transistor ST3 may be turned on in case that an initialization scan signal is applied to the initialization scan line GIL. In comparison, the second transistor ST2, the fourth transistor ST4, the fifth transistor ST5, and the sixth transistor ST6 are formed as p-type MOSFET, so they may be turned on in case that a scan signal with a gate low voltage and an emission signal are applied to the write scan line GWL, the bias scan line GBL, and the light emitting line EL, respectively.

By way of example, the fourth transistor ST4 in FIG. 4 may be formed of the n-type MOSFET. In this case, the active layer of each fourth transistor ST4 may be formed of the oxide semiconductor. In case that the fourth transistor ST4 is formed of n-type MOSFET, it may be turned on in case that a bias scan signal of a gate high voltage is applied to the bias scan line GBL.

By way of example, although not shown in FIGS. 4 and 5, the first to sixth transistors ST1, ST2, ST3, ST4, ST5, and ST6 and the driving transistor DT may all be formed as n-type MOSFET.

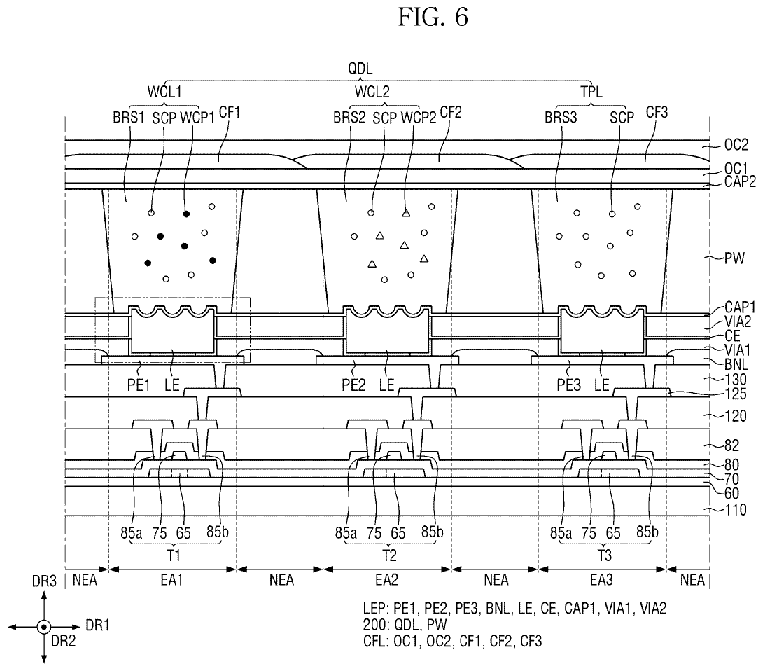

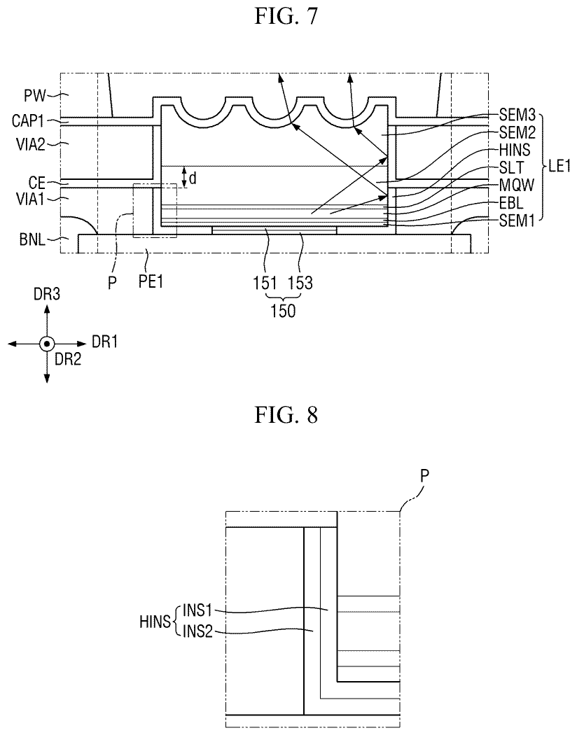

FIG. 6 is a schematic cross-sectional view schematically illustrating a display device according to one embodiment. FIG. 7 is a schematic cross-sectional view illustrating a pixel electrode and a light emitting element according to one embodiment. FIG. 8 is an enlarged view of area P in FIG. 7.

Referring to FIGS. 6 to 8, the display device 10 may include a substrate 110 and a light emitting element unit LEP disposed on the substrate 110. The substrate 110 may be an insulating substrate. The substrate 110 may include a transparent material. For example, the substrate 110 may include a transparent insulating material such as glass, quartz, etc. The substrate 110 may be a rigid substrate. However, the substrate 110 is not limited thereto and may include plastic such as polyimide and may have flexible characteristics that allow it to be curved, bent, folded, or rolled. A plurality of light emitting areas EA1, EA2, and EA3 and a non-emitting area NEA may be defined in the substrate 110.

Switching elements T1, T2, and T3 may be disposed on the substrate 110. In one embodiment, the first switching element T1 may be located (or disposed) in the first light emitting area EA1 of the substrate 110, the second switching element T2 may be located in the second light emitting area EA2, and the third switching element T3 may be located in the third light emitting area EA3. However, it is not limited thereto, and in an embodiment, at least one of the first switching element T1, the second switching element T2, and the third switching element T3 may be located in the non-emitting area (NEA).

In one embodiment, the first switching element T1, the second switching element T2, and the third switching element T3 may each be a thin film transistor including amorphous silicon, polysilicon, or an oxide semiconductor. Although not shown in the drawing, a plurality of signal lines (for example, gate lines, data lines, power supply lines, etc.) that transmit signals to each switching element may be further positioned on the substrate 110.

Each switching element T1, T2, and T3 may include a semiconductor layer 65, a gate electrode 75, a source electrode 85a, and a drain electrode 85b.

For example, a buffer layer 60 may be disposed on the substrate 110. The buffer layer 60 may be disposed to cover the entire surface of the substrate 110. The buffer layer 60 may include silicon nitride, silicon oxide, or silicon oxynitride, and may be made of a single layer or a double layer thereof.

The semiconductor layer 65 may be disposed on the buffer layer 60. The semiconductor layer 65 may form a channel for each switching element T1, T2, and T3. The semiconductor layer 65 may include amorphous silicon, polycrystalline silicon, or an oxide semiconductor. For example, the oxide semiconductor may include a binary compound (ABx), a ternary compound (ABxCy), or a tetracyclic compound (ABxCyDz) containing, for example, indium, zinc, gallium, tin, titanium, aluminum, hafnium (Hf), zirconium (Zr), magnesium (Mg), and the like within the spirit and scope of the disclosure. In one embodiment, the semiconductor layer 65 may include indium tin zinc oxide (IGZO).

The gate insulating layer 70 may be disposed on the semiconductor layer 65. The gate insulating layer 70 may include a silicon compound, metal oxide, or the like within the spirit and scope of the disclosure. For example, the gate insulating layer 70 may include a silicon oxide, a silicon nitride, a silicon oxynitride, an aluminum oxide, a tantalum oxide, a hafnium oxide, a zirconium oxide, a titanium oxide, and the like within the spirit and scope of the disclosure. In one embodiment, the gate insulating layer 70 may include silicon oxide.

The gate electrode 75 may be disposed on the gate insulating layer 70. The gate electrode 75 may be disposed to overlap the semiconductor layer 65. The gate electrode 75 may include a conductive material. The gate electrode 75 may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be made of a Cu/Ti double layer in which an upper layer of copper is stacked on a lower layer of titanium but is not limited thereto.

A first interlayer insulating layer 80 and a second interlayer insulating layer 82 may be disposed on the gate electrode 75. The first interlayer insulating layer 80 may be directly disposed on the gate electrode 75, and the second interlayer insulating layer 82 may be directly disposed on the first interlayer insulating layer 80. The first interlayer insulating layer 80 and the second interlayer insulating layer 82 each include an inorganic insulating material such as silicon oxide, silicon nitride, silicon oxynitride, hafnium oxide, aluminum oxide, titanium oxide, tantalum oxide, zinc oxide, and the like within the spirit and scope of the disclosure. However, the disclosure is not limited thereto, and the second interlayer insulating layer 82 may include an organic insulating material capable of flattening the lower-level difference. In this embodiment, two interlayer insulating layers, the first interlayer insulating layer 80 and the second interlayer insulating layer 82, are illustrated and described, but the disclosure is not limited thereto, and only one interlayer insulating layer may be disposed.

The source electrode 85a and the drain electrode 85b may be disposed on the second interlayer insulating layer 82. The source electrode 85a and the drain electrode 85b may contact the semiconductor layer 65 through contact holes penetrating the first interlayer insulation layer 80, the second interlayer insulation layer 82, and the gate insulation layer 70, respectively. The source electrode 85a and the drain electrode 85b may include metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be made of a Cu/Ti double layer in which an upper layer of copper is stacked on a lower layer of titanium but is not limited thereto.

A first planarization layer 120 may be disposed on the first switching element T1, the second switching element T2, and the third switching element T3. The first planarization layer 120 may include an organic material. For example, the first planarization layer 120 may include acrylic resin, epoxy resin, imide resin, ester resin, etc. In one embodiment, the first planarization layer 120 may include a positive photosensitive material or a negative photosensitive material.

A pixel connection electrode 125 may be disposed on the first planarization layer 120. The pixel connection electrode 125 is disposed to correspond to each of the first switching element T1, the second switching element T2, and the third switching element T3, and may be electrically connected to them. The pixel connection electrode 125 may connect the pixel electrodes PE1, PE2, and PE3 described later to the switching elements T1, T2, and T3 described above. The pixel connection electrode 125 may contact the switching elements T1, T2, and T3 through a contact hole penetrating the first planarization layer 120.

A second planarization layer 130 may be disposed on the first planarization layer 120 and the pixel connection electrode 125. The second planarization layer 130 flattens the lower-level difference and may include the same material as the first planarization layer 120 described above.

The light emitting element unit LEP may be disposed on the second planarization layer 130. The light emitting element unit LEP may include a plurality of pixel electrodes PE1, PE2, and PE3, a plurality of light emitting elements LE, and a common electrode CE. Additionally, the light emitting element unit LEP may further include a bank layer BNL, a first via layer VIA1, and a second via layer VIA2 that compartmentalize each of the light emitting areas EA1, EA2, and EA3.

The bank layer BNL separates the light emitting area EA1, EA2, and EA3 and the non-emitting area NEA. The bank layer BNL may include a polyacrylates resin, an epoxy resin, a phenolic resin, a polyamides resin, a polyimides rein, unsaturated polyesters resin, poly phenylenethers resin, polyphenylenesulfides resin, or benzocyclobutene (BCB).

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as the first electrode of the light emitting element LE and may be an anode electrode or a cathode electrode. The first pixel electrode PE1 may be located in the first light emitting area EA1, the second pixel electrode PE2 may be located in the second light emitting area EA2, and the third pixel electrode PE3 may be located in the third light emitting area EA3. In one embodiment, the first pixel electrode PE1 may overlap the first light emitting area EA1, the second pixel electrode PE2 may overlap the second light emitting area EA2, and the third pixel electrode PE1 may overlap the third light emitting area EA3.

Each pixel electrode PE1, PE2, and PE3 may be directly connected to the pixel connection electrode 125 through a contact hole penetrating the second planarization layer 130 and may be electrically connected to the respective switching elements T1, T2, and T3 through the pixel connection electrode 125. The first pixel electrode PEI, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Additionally, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but the structure is not limited thereto.

In this embodiment, each pixel electrode PE1, PE2, and PE3 is illustrated as a single layer, but it is not limited thereto and may be formed as a multi-layer. For example, each pixel electrode PE1, PE2, and PE3 may include a lower electrode layer and an upper electrode layer. The lower electrode layer is disposed at the bottom of the pixel electrode and may serve to provide adhesion to the second planarization layer 130. The lower electrode layer may include a metal, for example, titanium. The upper electrode layer may be disposed on the lower electrode layer and directly contact the light emitting element LE. The upper electrode layer may be disposed between the lower electrode layer and the light emitting element LE and may serve to provide adhesion to the light emitting element LE to each pixel electrode PEI, PE2, and PE3. The upper electrode layer may include a metal, for example, copper.

The plurality of light emitting elements LE may be disposed on the first pixel electrode PE1, the second pixel electrode PE2, and the third pixel electrode PE3.

As shown in FIGS. 6 and 7, the light emitting elements LE may be disposed in each of the first light emitting area EA1, the second light emitting area EA2, and the third light emitting area EA3.

The light emitting element LE may be a micro light emitting diode element. The light emitting element LE may include a connection electrode 150, a first semiconductor layer SEM1, an electronic blocking layer EBL, an active layer MQW, a superlattice layer SLT, a second semiconductor layer SEM2, and a third semiconductor layer SEM3 in the thickness direction of the substrate 110, for example, the third direction DR3. The connection electrode 150, the first semiconductor layer SEM1, the electronic blocking layer EBL, the active layer MQW, the superlattice layer SLT, the second semiconductor layer SEM2, and the third semiconductor layer SEM3 may be stacked sequentially in the third direction DR3. One or both of the electron blocking layer EBL and superlattice layer SLT may be omitted. The light emitting element LE may include a heterogeneous insulating layer HINS surrounding at least a portion of the first semiconductor layer SEM1, the superlattice layer SLT, the active layer MQW, the electronic blocking layer EBL, and the second semiconductor layer SEM2.

The light emitting element LE may have a cylindrical, disk, or rod shape. However, it is not limited to this, and the light emitting element LE may have a shape such as a rod, wire, tube, or the like, a polygonal shape such as a cube, a rectangle, a hexagon, or the like, or a shape that extends in one direction but has a partially sloped outer surface.

The connection electrode 150 may be disposed on top of each of the plurality of pixel electrodes PE1, PE2, and PE3. In the following, the light emitting element LE disposed on the first pixel electrode PE1 will be described as an example, but is not limited thereto, and the structure of the light emitting element LE disposed on the second pixel electrode PE2 and the third pixel electrode PE3 may be formed in the same manner.

The connection electrode 150 may include a reflective layer 151 and a connection layer 153. The reflective layer 151 may serve to reflect light emitted from the active layer MQW of the light emitting element LE. The reflective layer 151 may be disposed adjacent to the active layer MQW of the light emitting element LE. The reflective layer 151 may include a metal material that is conductive and has a high light reflectance. The reflective layer 151 may include, for example, aluminum (Al) or silver (Ag), or may be an alloy thereof.

The connection layer 153 may serve to transmit a light emitting signal from the first pixel electrode PEI to the light emitting element LE. The connection layer 153 may be an ohmic connection electrode. However, it may be a Schottky connection electrode. The connection layer 153 may be disposed at the bottom of the light emitting element LE and may be disposed farther from the active layer MQW compared to the reflective layer 151. The connection layer 153 may include at least one of gold (Au), copper (Cu), tin (Sn), silver (Ag), aluminum (Al), and titanium (Ti). For example, the connection layer 153 may include a 9:1 alloy, 8:2 alloy, or 7:3 alloy of gold and tin, or may include an alloy of copper, silver, and tin (SAC305).

In FIG. 8, the light emitting element LE illustrates the connection electrode 150 having a double-layer structure of one reflective layer 151 and the connection layer 153, but the light emitting element LE is not limited thereto. In some cases, the light emitting element LE may include the connection electrode 150 with a greater number of layers stacked, or some layers may be omitted.

The first semiconductor layer SEM1 may be disposed on the connection electrode 150. The first semiconductor layer SEM1 may be disposed adjacent to the first pixel electrode PE1. The first semiconductor layer SEM1 may be a p-type semiconductor and may include a semiconductor material having a chemical formula of AlxGayIn1-x-yN(0≤x≤1,0≤y≤1, 0≤x+y≤1). For example, it may be any one or more of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, or the like within the spirit and scope of the disclosure. For example, the first semiconductor layer SEM1 may be p-GaN doped with p-type Mg. The thickness of the first semiconductor layer SEM1 may range from 30 nm to 200 nm but is not limited thereto.

The electron blocking layer EBL may be disposed on the first semiconductor layer SEM1. The electron blocking layer EBL may be a layer to suppress or prevent too many electrons from flowing into the active layer MQW. For example, the electron blocking layer EBL may be p-AlGaN doped with p-type Mg. The thickness of the electron blocking layer EBL may range from 10 nm to 50 nm but is not limited thereto. Additionally, the electron blocking layer EBL may be omitted.

The active layer MQW may be disposed on the first semiconductor layer SEM1. The active layer MQW may emit light by combining electron-hole pairs according to electrical signals applied through the first semiconductor layer SEMI and the second semiconductor layer SEM2. The active layer MQW may emit first light having a central wavelength range of about 450 nm to about 495 nm, for example, light in a blue wavelength band.

The active layer MQW may include a single or multiple quantum well structure. If the active layer may include a material with a multi-quantum well structure, it may be a stacked structure with a plurality of well layers and a barrier layer alternating with each other. In this case, the well layer may be formed of InGaN and the barrier layer may be formed of GaN or AlGaN, but is not limited thereto. The thickness of the well layer may be in a range of about 1 to about 4 nm, and the thickness of the barrier layer may be in a range of about 3 nm to about 10 nm.

By way of example, the active layer MQW may have a structure in which a semiconductor material having a large band gap energy and a semiconductor material having a small band gap energy are alternately stacked each other and may include other Group 3 to Group 5 semiconductor materials depending on the wavelength band of the emitted light. The light emitted from the active layer MQW is not limited to the first light and may emit second light (light of a green wavelength band) or third light (light of a red wavelength band) according to circumstances. In one embodiment, in case that indium is included among the semiconductor materials included in the active layer MQW, the color of emitted light may vary according to the amount of indium. For example, in case that the indium content is about 15%, the light in a blue wavelength band may be emitted, in case that the indium content is about 25%, the light in a green wavelength band may be emitted, and in case that the indium content is about 35% or more, the light in a red wavelength band may be emitted.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN or GaN. The thickness of the superlattice layer SLT may be in a range of about 50 to about 200 nm. The superlattice layer SLT may be omitted.

The second semiconductor layer SEM2 may be disposed on the superlattice layer SLT. In case that the superlattice layer SLT is omitted, the second semiconductor layer SEM2 may be disposed on the active layer MQW. The second semiconductor layer SEM2 may be an n-type semiconductor. The second semiconductor layer SEM2 may include a semiconductor material having the chemical formula AlxGayIn1-x-yN(0≤x≤1,0≤y≤1, 0≤x+y≤1). For example, it may be one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like within the spirit and scope of the disclosure. For example, the second semiconductor layer SEM2 may be n-GaN doped with n-type Si. The thickness of the second semiconductor layer SEM2 may range from 2 μm to 4 μm but is not limited thereto.

The third semiconductor layer SEM3 may be disposed on the second semiconductor layer SEM2.

The third semiconductor layer SEM3 may have a concave-convex structure on its upper surface. For example, the third semiconductor layer SEM3 may be an undoped semiconductor grown on PSS. The third semiconductor layer SEM3 may include the same material as the second semiconductor SEM2 but may be a material undoped with an n-type or p-type dopant. In one embodiment, the third semiconductor layer SEM3 may be at least one of undoped InAlGaN, GaN, AlGaN, InGaN, AlN, and InN but is not limited thereto.

The heterogeneous insulating layer HINS may surround the sides of the light emitting element LE, for example, the outer peripheral surface. The heterogeneous insulating layer HINS may insulate the light emitting elements LE from other layers. The heterogeneous insulating layer HINS may be directly disposed on the outer peripheral surface of the first semiconductor layer SEM1, the second semiconductor layer SEM2, and the active layer MQW to surround them. In one embodiment, the heterogeneous insulating layer HINS may surround the entire outer peripheral surface of the first semiconductor layer SEM1 and the active layer MQW. The heterogeneous insulating layer HINS may surround at least a portion of the outer peripheral surface of the second semiconductor layer SEM2. The heterogeneous insulating layer HINS may expose at least a portion of the second semiconductor layer SEM2. The distance d from the interface of the third semiconductor layer SEM3 and the second semiconductor layer SEM2 to the end of the heterogeneous insulating layer HINS may be at least 20 nm. The distance d to the end of the heterogeneous insulating layer HINS is equal to the step d between the heterogeneous insulating layer HINS and the second semiconductor layer SEM2.

As shown in FIG. 8, the heterogeneous insulating layer HINS may include two or more insulating layers having different refractive indices. For example, the heterogeneous insulating layer HINS may include a first insulating layer INS1 and a second insulating layer INS2. The second insulating layer INS2 may be disposed further outside the light emitting element LE than the first insulating layer INS1. For example, the first insulating layer INS1 may directly contact the first semiconductor layer SEM1, the active layer MQW, and the second semiconductor layer SEM2.

The refractive index of the second insulating layer INS2 may be smaller than the refractive index of the first insulating layer INS1. The difference between the refractive index of the second insulating layer INS2 and the refractive index of the first insulating layer INS1 may be about 0.4 or more. Due to the difference between the refractive index of the second insulating layer INS2 and the first insulating layer INS1, the light traveling from the active layer MQW toward the side of the light emitting element LE rather than the top may be reflected. As a result, the luminous efficiency of the light emitting element LE may be increased.

The bandgap of the first insulating layer INS1 and the second insulating layer INS2 may be 3.4 or more.

The first insulating layer INS1 and the second insulating layer INS2 may include materials having different refractive indices but may include inorganic insulating materials such as silicon oxide (SiOₓ), silicon nitride (SiNₓ), silicon oxynitride (SiOₓN_{y}), aluminum oxide (AlₓO_{y}), aluminum nitride (AlN), and the like within the spirit and scope of the disclosure. The thickness of the first insulating layer INS1 and the second insulating layer INS2 may be about 0.1 μm but is not limited thereto.

The heterogeneous insulating layer HINS may insulate between the common electrode CE and the connection electrode 150. The first via layer VIA1 may be disposed on the second planarization layer 130 where the light emitting element LE is not disposed.

The first via layer VIA1 may prevent underlying components from being damaged during the etching process of the light emitting element LE, which will be described later. For example, the first via layer VIA1 may protect the lower heterogeneous insulating layer HINS. The first via layer VIA1 may be formed to a selectable height. For example, the height of the first via layer VIA1 may be smaller than the height of the second semiconductor layer SEM2 of the light emitting element LE. The first via layer VIA1 may be formed at a selectable height so that at least a portion of the plurality of light emitting elements LE, for example, the second semiconductor layer SEM2, may protrude above the first via layer VIA1. For example, the height of the first via layer VIA1 may be smaller than the height of the light emitting element LE. The step difference d between the first via layer VIA1 and the second semiconductor layer SEM2 may be about 20 nm or more.

The height of the first via layer VIA1 and the height of the heterogeneous insulating layer HINS may be the same.

The height of the first via layer VIA1 and the height of the heterogeneous insulating layer HINS may refer to the height from the second planarization layer 130 to the highest point in the thickness direction.

The first via layer VIA1 may include an organic material to flatten the lower step. For example, the first via layer VIA1 may include a polyacrylates resin, an epoxy resin, a phenolic resin, a polyamides resin, a polyimides rein, unsaturated polyesters resin, poly phenylenethers resin, polyphenylenesulfides resin, or benzocyclobutene (BCB).

The common electrode CE may be disposed on the side surfaces of the first via layer VIA1 and the light emitting element LE. The common electrode CE is disposed along the side of the second semiconductor layer SEM2 exposed by the third semiconductor layer SEM3 and the first via layer VIA1 of the light emitting element LE and extends over the first via layer VIA1. The common electrode CE may be disposed entirely in the display area DA of the substrate 110 where the light emitting element LE is not disposed. The common electrode CE may directly contact the second semiconductor layer SEM2 exposed on the top surface of the light emitting element LE. The common electrode CE may be in direct contact with the second semiconductor layer SEM2 and the third semiconductor layer SEM3 of each light emitting element LE so that a common voltage may be applied to each light emitting element LE. The common electrode CE may be a common layer arranged to commonly connect a plurality of light emitting elements LE. Since the common electrode CE is disposed entirely on the substrate 110 and applies a common voltage, it may include a material with low resistance. The common electrode CE may be an Ohmic electrode but is not limited thereto.

The common electrode CE may include a metal material with low resistance such as aluminum (Al), silver (Ag), copper (Cu), or the like, or a metal oxide, such as ITO, IZO, ITZO, or the like within the spirit and scope of the disclosure. Since the common electrode CE is not disposed on the top surface of the light emitting element LE, it may include a metal material (f, aluminum (Al) or silver (Ag)) that is conductive and has a high light reflectance.

Referring to FIG. 7, the common electrode CE and the heterogeneous insulating layer HINS surround the side of the light emitting element LE. The common electrode CE and the heterogeneous insulating layer HINS may emit light from the active layer MQW of the light emitting element LE and reflect the light emitted laterally toward the top (for example, in the third direction DR3). For example, the common electrode CE and the heterogeneous insulating layer HINS may improve the light emitting efficiency of the light emitting element LE

The second via layer VIA2 may be disposed on the common electrode CE where the light emitting element LE is not disposed. The second via layer VIA2 covers the common electrode CE and may directly contact the common electrode CE. The second via layer VIA2 may be formed at a selectable height so that at least a portion of the plurality of light emitting elements LE, for example, the third semiconductor layer SEM3, may protrude above the second via layer VIA2. For example, the height of the second via layer VIA2 may be smaller than the height of the light emitting element LE.

The second via layer VIA2 may be entirely disposed in the display area DA of the substrate 110.

The second via layer VIA2 may include an organic material to flatten the lower step. For example, the second via layer VIA2 may comprise a polyacrylates resin, an epoxy resin, a phenolic resin, a polyamides resin, a polyimides rein, unsaturated polyesters resin, poly phenylenethers resin, polyphenylenesulfides resin, or benzocyclobutene (BCB).

The light emitting element unit LEP may further include a first capping layer CAP1 covering the common electrode CE.

The first capping layer CAP1 may be directly disposed on the common electrode CE. The first capping layer CAP1 extends from the top surface of the light emitting element LE along the side surface to the second via layer VIA2.

The first capping layer CAP1 may be disposed between a wavelength control unit (or wavelength controller) 200 and the light emitting element unit LEP to insulate the wavelength control unit 200 and the light emitting element unit LEP. For example, the first capping layer CAP1 may separate the wavelength control unit 200 and the light emitting element LE from each other.

The first capping layer CAP1 may be disposed in direct contact with the third semiconductor layer SEM3 of the light emitting element LE.

The first capping layer CAP1 may include an inorganic material. For example, the first capping layer CAP1 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxide. The drawing illustrates that the first capping layer CAP1 is formed as one layer, but the disclosure is not limited thereto. For example, the first capping layer CAP1 may be formed as multiple layers stacked with alternating inorganic layers including at least one of the materials described above as materials that the first capping layer CAP1 may include. The thickness of the first capping layer CAP1 may be in a range about 0.05 μm to about 2 μm but is not limited thereto.

The display device 10 according to one embodiment may reflect light emitted from the light emitting element LE to the top by including the heterogeneous insulating layer HINS and the common electrode CE surrounding the side of the light emitting element LE. Accordingly, the first heterogeneous insulating layer HINS and the common electrode CE may improve the light output efficiency of the light emitting element LE.

The wavelength control unit 200 may be disposed on the light emitting element unit LEP. The wavelength control unit 200 may include a wavelength conversion layer QDL and a partition wall PW.

The wavelength control unit 200 is disposed on the first capping layer CAP1 and may compartmentalize a plurality of light emitting areas EA1, EA2, and EA3. The wavelength control unit 200 is arranged to extend in the first direction DR1 and the second direction DR2 and may be formed in a grid-like pattern throughout the display area DA. Further, the wavelength control unit 200 may not overlap the plurality of light emitting areas EA1, EA2, and EA3 and may overlap the non-emitting area NEA.

The partition wall PW may serve to provide space for the wavelength conversion layer QDL to be formed. The partition wall PW may be made relatively thick to provide a space in which the wavelength conversion layer QDL is formed. For example, the thickness of the partition wall PW may be in the range of 1 μm to 10 μm, respectively. The partition wall PW may include an organic insulating material so that it may have a relatively large thickness. The organic insulating material may include, for example, an epoxy-based resin, an acrylic-based resin, a cado-based resin, or an imide-based resin.

In one embodiment, the partition wall PW may block the transmission of light in the non-emitting area NEA. The partition wall PW may further include a light blocking material and may include a dye or pigment having light blocking properties. For example, the partition wall PW may be a black matrix. External light incident from the outside of the display device 10 may cause a problem that distorts the color gamut of the wavelength control unit 200. According to this embodiment, the partition wall PW including a light-blocking material is disposed in the wavelength control unit 200 so that at least a portion of external light is absorbed by the light-blocking material. Therefore, color distortion caused by external light reflection may be reduced. Furthermore, the partition wall PW containing a light-blocking material may prevent light from intruding between adjacent light-emitting areas and causing color mixing, thereby further improving the color reproduction rate. In this embodiment, a single-layer partition wall PW is illustrated and described, but the disclosure is not limited thereto, and the partition wall PW may be made of multiple layers.

The wavelength conversion layer QDL may be disposed on each light emitting area EA1, EA2, and EA3. The wavelength conversion layer QDL may convert or shift the peak wavelength of incident light into light of another given peak wavelength and emit it. The wavelength conversion layer QDL may convert the blue first light emitted by the light emitting element LE into a red second light, a green third light, or transmit the blue first light as it is.

The wavelength conversion layer QDL may be disposed in each light emitting area EA1, EA2, and EA3 compartmentalized by the partition wall PW and may be disposed to be spaced apart from each other. For example, the wavelength conversion layer QDL may be formed in the island pattern spaced apart from each other. The wavelength conversion layer QDL may be disposed to overlap the first light emitting area EA1, the second light emitting area EA2, and the third light emitting area EA3, respectively. In one embodiment, each of the wavelength conversion layer QDL may completely overlap the first light emitting area EA1, the second light emitting area EA2, and the third light emitting area EA3.

The wavelength conversion layer QDL may include a first wavelength conversion pattern WCL1 overlapping the first light emitting area EA1, a second wavelength conversion pattern WCL2 overlapping the second light emitting area EA2, and a light transmission pattern TPL overlapping the third light emitting area EA3.

The first wavelength conversion pattern WCL1 may be disposed to overlap the first light emitting area EA1. The first wavelength conversion pattern WCL1 may convert or shift the peak wavelength of incident light into light of another given peak wavelength and emit the light. In one embodiment, the first wavelength conversion pattern WCL1 may convert and emit blue first light emitted from the light emitting element LE of the first light emitting area EA1 into second light, which is red light having a single peak wavelength in the range of about 610 nm to about 650 nm.

The first wavelength conversion pattern WCL1 may include a first base resin BRS1, a first wavelength conversion particle WCP1, and a scatterer SCP. The first base resin BRS1 may include a light transmitting organic material. For example, the first base resin BRS1 may include the epoxy-based resin, the acrylic-based resin, the cardo-based resin, or the imide-based resin.

The first wavelength conversion particle WCP1 may convert the first light incident from the light emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, or a phosphorescent material. For example, quantum dots may be particulate materials that emit a given color as electrons transition from the conduction band to the valence band.

The quantum dots may be semiconductor nanocrystalline materials. Depending on its composition and size, the quantum dot may have a given bandgap to absorb light and emit light with a unique wavelength. Examples of the semiconductor nanocrystals of the quantum dots include IV group nanocrystals, II-VI group compound nanocrystals, III-V group compound nanocrystals, IV-VI group nanocrystals, or combinations thereof.

The group II-VI compound is a binary compound selected from the group consisting of CdSe, CdTe, ZnS, ZnSe, ZnTe, ZnO, HgS, HgSe, HgTe, MgSe, MgS, and mixtures thereof; InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and ternary compounds selected from the group consisting of mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnST, and mixtures thereof.

The group III-V compound is a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one embodiment, the quantum dot may have a core-shell structure including a core including a nanocrystal as described above and a shell surrounding the core. The shell of the quantum dot may act as a protective layer to prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄, but the disclosure is not limited thereto.

The semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. but are not limited thereto.

The scatterer SCP may scatter the light of the light emitting element LE in a random direction. The scatterer SCP may have a different refractive index from the base resin BRS1 and form an optical interface with the base resin BRS1. For example, the scatterer SCP may be a light scattering particle. The scatterer SCP is not particularly limited to any material capable of scattering at least a portion of the transmitted light, but may be, for example, metal oxide particles or organic particles. Examples of the metal oxide include titanium oxide (TiO₂), zirconium oxide (ZrO₂), aluminum oxide (Al₂O₃), indium oxide (In₂O₃), zinc oxide (ZnO), and tin oxide (SnO₂), and examples of organic particle materials include acrylic resins or urethane resins. The scatterer SCP may scatter light in a random direction regardless of the incident direction of the incident light without substantially converting the wavelength of the light.

The second wavelength conversion pattern WCL2 may be disposed to overlap the second emitting area EA2. The second wavelength conversion pattern WCL2 may emit light by converting or shifting the peak wavelength of incident light into light of another given peak wavelength. In one embodiment, the second wavelength conversion pattern WCL2 converts the blue first light emitted from the light emitting element LE of the second light emitting area EA2 into green third light having a peak wavelength in the range of about 510 nm to 550 nm and emit it.

The second wavelength conversion pattern WCL2 may include a second base resin BRS2 and a second wavelength conversion particle WCP2 and the scatterer SCP dispersed in the second base resin BRS2.

The second base resin BRS2 may be made of a material with high light transmittance, may be made of the same material as the first base resin BRS1, or may include at least one of the materials described as their constituent materials.

The second wavelength conversion particle WCP2 may convert or shift the peak wavelength of incident light to another given peak wavelength. In one embodiment, the second wavelength conversion particle WCP2 may convert the blue first light provided from the light emitting element LE into green third light having a peak wavelength in the range of about 510 nm to 550 nm and emit it. Examples of the second wavelength conversion particle WCP2 include quantum dots, quantum rods, or phosphors. A more detailed description of the second wavelength conversion particle WCP2 may be substantially the same as or similar to that described above in the description of the first wavelength conversion particle WCP1 and may be omitted.

The light transmission pattern TPL may be arranged to overlap the third light emitting area EA3. The light transmission pattern TPL may transmit incident light. The light transmission pattern TPL may directly transmit the blue first light emitted from the light emitting element LE disposed in the third light emitting area EA3. The light transmission pattern TPL may include a third base resin BRS3 and the scatterer SCP dispersed in the third base resin BRS3. Since the third base resin BRS3 is substantially the same as or similar to the above-described first base resin BRS1, description thereof will be omitted.

The first light, second light, and third light emitted from the above-described wavelength control unit 200 may respectively pass through a color filter layer CFL, which will be described later, to implement full color.

The wavelength control unit 200 may further include a second capping layer CAP2 disposed on the wavelength conversion layer QDL. The second capping layer CAP2 serves to cover the wavelength conversion layer QDL disposed underneath and protect it from moisture or debris. The second capping layer CAP2 may include an inorganic material and may include a material that is substantially the same as or similar to the above-described first capping layer CAP1.

The color filter layer CFL may be disposed on the wavelength control unit 200. The color filter layer CFL may include a first overcoat layer OC1, a first color filter CF1, a second color filter CF2, a third color filter CF3, and a second overcoat layer OC2.

The first overcoat layer OC1 may be disposed on the wavelength control unit 200. The first overcoat layer OC1 may be directly disposed on the second capping layer CAP2 of the wavelength control unit 200. The first overcoat layer OC1 may be disposed entirely over the display area DA and may have a flat surface. The first overcoat layer OC1 may flatten the step formed by the lower wavelength control unit 200 to facilitate the formation of the color filter layer CFL.

The first overcoat layer OC1 may include a light-transmitting organic material. For example, the first overcoat layer OC1 may include epoxy resin, acrylic resin, cardo resin, or imide resin.

The first color filter CF1, the second color filter CF2, and the third color filter CF3 may be disposed on the first overcoat layer OC1. The first color filter CF1 may be disposed in the first emitting area EA1, the second color filter CF2 may be disposed in the second emitting area EA2, and the third color filter CF3 may be disposed in the third emitting area EA3.

The first color filter CF1, the second color filter CF2, and the third color filter CF3 may include a colorant such as the dye or pigment that absorbs wavelengths other than the corresponding color wavelength. The first color filter CF1 may selectively transmit the second light (for example, red light) and block or absorb the first light (for example, blue light) and the third light (for example, green light). The second color filter CF2 may selectively transmit the third light (for example, green light) and block or absorb the first light (for example, blue light) and the second light (for example, red light). The third color filter CF3 may selectively transmit the first light (for example, blue light) and block or absorb the second light (for example, red light) and the third light (for example, green light). For example, the first color filter CF1 may be a red color filter, the second color filter CF2 may be a green color filter, and the third color filter CF3 may be a blue color filter.

In one embodiment, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to the top of the substrate 110 to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may prevent color distortion due to reflection of external light.

The plane area of each of the first color filter CF1, the second color filter CF2, and the third color filter CF3 may be larger than the planar area of each of the plurality of light emitting areas EA1, EA2, and EA3. For example, the first color filter CF1 may be larger than the planar area of the first emitting area EA1. The second color filter CF2 may be larger than the planar area of the second emitting area EA2. The third color filter CF3 may be larger than the planar area of the third emitting area EA3. However, it is not limited thereto, and the planar area of each of the first color filter CF1, the second color filter CF2, and the third color filter CF3 may be equal to the planar area of each of the plurality of light emitting areas EA1, EA2, and EA3.

The second overcoat layer OC2 may be disposed on the color filter layer CFL. The second overcoat layer OC2 may be directly disposed on the color filter layer CFL. The second overcoat layer OC2 may be disposed entirely in the display area DA and may have a flat surface. The second overcoat layer OC2 may flatten the step formed by the lower color filter layer CFL. The second overcoat layer OC2 may include a light-transmitting organic material and may be substantially the same as or similar to the first overcoat layer OC1 described above.

The embodiment describes an embodiment including the wavelength control unit 200 but is not limited thereto. In case that the light emitting elements LE disposed in different light emitting areas EA1, EA2, and EA3 emit light of different wavelengths, the wavelength control unit 200 may be omitted. For example, the light emitting element LE disposed in the first light emitting area EA1 may be arranged to emit red light having a single peak wavelength in the range of about 610 nm to about 650 nm, the light emitting element LE disposed in the second light emitting area EA2 may emit green light having a peak wavelength in the range of about 510 nm to 550 nm, and the light emitting element LE disposed in the third light emitting area EA3 may be arranged to emit blue light having a peak wavelength in the range of about 450 nm to 500 nm. In this way, in case that the light emitting elements LE that emit light of different wavelengths are disposed in the first light emitting area EA1, the second light emitting area EA2, and the third light emitting area EA3, the wavelength control unit 200 may be omitted, and the color filter layer CFL may be directly disposed on the light emitting element unit LEP.

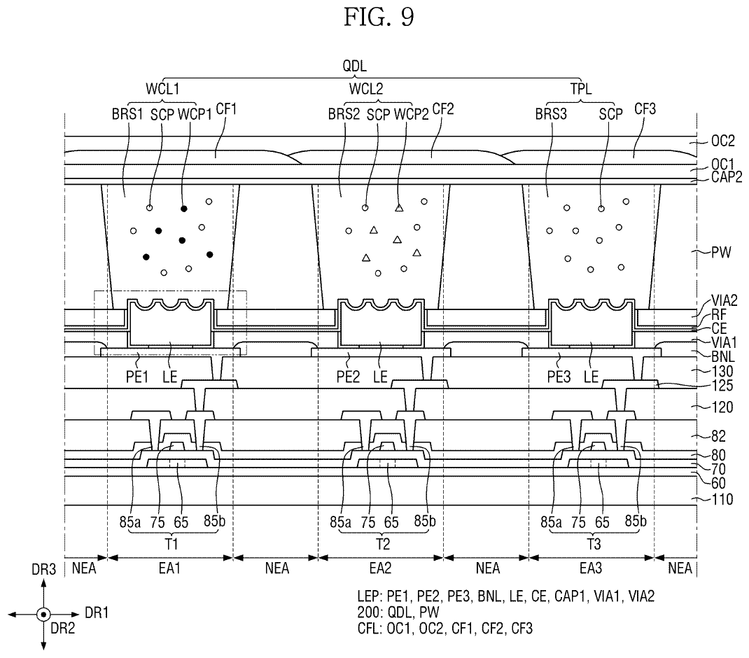

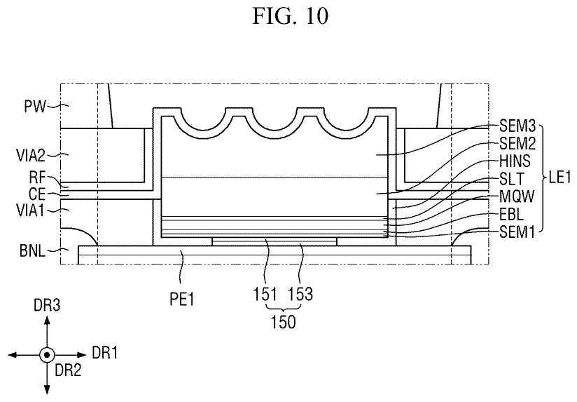

FIG. 9 is a schematic cross-sectional view schematically illustrating a display device according to an embodiment. FIG. 10 is a schematic cross-sectional view illustrating a pixel electrode and a light emitting element according to the embodiment of FIG. 9.

Referring to FIGS. 9 and 10, the common electrode CE is also disposed on the top of the light emitting element LE, and the reflective layer RF surrounding the side of the light emitting element LE is disposed on the common electrode CE, which differs from the embodiments of FIGS. 6 to 8 above. Hereinafter, descriptions overlapping with the above-described embodiment will be omitted and differences will be described.

The common electrode CE covers the light emitting element LE and may be disposed to contact the side surfaces of the third semiconductor layer SEM3 and the second semiconductor layer SEM2.

Since the common electrode CE is disposed on the light emitting element LE, it may be formed with a thin thickness to facilitate light transmission in consideration of transparency. The common electrode CE may include a metal material with low resistance such as aluminum (Al), silver (Ag), copper (Cu), or the like, or a metal oxide such as ITO, IZO, ITZO, or the like within the spirit and scope of the disclosure. The thickness of the common electrode CE may be in a range of about 10 Å to about 200 Å but is not limited thereto.

The reflective layer RF may be disposed on the common electrode CE, surround the side surface of the light emitting element LE, and extend in the third direction DR3. The reflective layer RF is in direct contact with the common electrode CE. The reflective layer RF may include a metal material with high light reflectance. The reflective layer RF may include, for example, aluminum (Al) or silver (Ag), or may be an alloy thereof. As described above, the reflective layer RF may include a metal material with high light reflectance and is therefore not disposed on the light emitting element LE.

Unlike the above-described embodiment, the reflective layer RF may be disposed only on the side of the light emitting element LE. Since the reflective layer RF is formed on the side of the light emitting element LE, a mask process for manufacturing the reflective layer RF may be omitted. The reflective layer RF may surround the side surfaces of the second semiconductor layer SEM2 and the third semiconductor layer SEM3 of the light emitting element LE. For example, the reflective layer RF may surround the entire side of the third semiconductor layer SEM3 and cover a portion of the side of the second semiconductor layer SEM2.

As described above, by forming the reflective layer RF surrounding each light emitting element LE, light emitted from the light emitting element LE to the side may be reflected upward. Accordingly, the reflective layer RF may improve the light emission efficiency of the light emitting element LE.

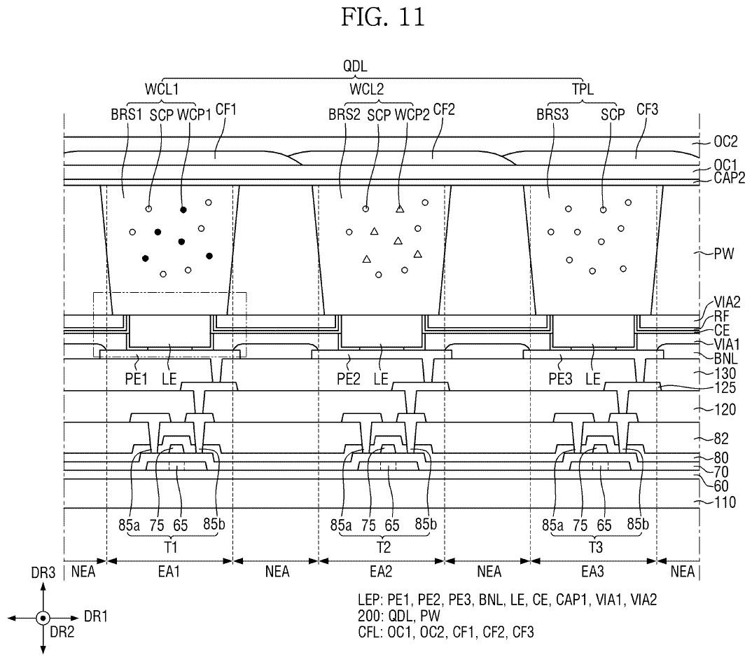

FIG. 11 is a schematic cross-sectional view schematically illustrating a display device according to an embodiment. FIG. 12 is a schematic cross-sectional view illustrating a pixel electrode and a light emitting element according to the embodiment of FIG. 11.

Referring to FIGS. 11 and 12, the light emitting element LE differs from the embodiments of FIGS. 6 to 8 in that it does not include the third semiconductor layer SEM3. Hereinafter, descriptions overlapping with the above-described embodiment will be omitted and differences will be described.

The light emitting element LE may include the connection electrode 150, the first semiconductor layer SEM1, the electron blocking layer EBL, the active layer MQW, the superlattice layer SLT, and the second semiconductor layer SEM2 in the thickness direction of the substrate 110, for example, the third direction DR3. The connection electrode 150, the first semiconductor layer SEM1, the electron blocking layer EBL, the active layer MQW, the superlattice layer SLT, and the second semiconductor layer SEM2 may be stacked sequentially in the third direction DR3. One or both of the electron blocking layer EBL and superlattice layer SLT may be omitted. The light emitting element LE may include the heterogeneous insulating layer HINS surrounding at least a portion of the first semiconductor layer SEM1, the superlattice layer SLT, the active layer MQW, the electron blocking layer EBL, and the second semiconductor layer SEM2.

The common electrode CE is disposed along the side of the second semiconductor layer SEM2 exposed by the first via layer VIA1 and extends on the first via layer VIA1. The common electrode CE may be disposed entirely in the display area DA of the substrate 110 where the light emitting element LE is not disposed. The common electrode CE may directly contact the second semiconductor layer SEM2 exposed on the top surface of the light emitting element LE. The common electrode CE may directly contact the second semiconductor layer SEM2 of each light emitting element LE so that a common voltage may be applied to each light emitting element LE. The common electrode CE may be a common layer disposed in common connection with the plurality of light emitting elements LE. Since the common electrode CE is disposed entirely on the substrate 110 and applies a common voltage, it may include a material with low resistance. The common electrode CE may be the Ohmic electrode but is not limited thereto.

The common electrode CE may include a metal material with low resistance such as aluminum (Al), silver (Ag), copper (Cu), or a metal oxide such as ITO, IZO, ITZO, or the like within the spirit and scope of the disclosure. Since the common electrode CE is not disposed on the top surface of the light emitting element LE, it may include a metal material (for example, aluminum (Al) or silver (Ag)) that is conductive and has a high light reflectance.

The second via layer VIA2 may be disposed on the common electrode CE where the light emitting element LE is not disposed. The second via layer VIA2 covers the common electrode CE and may directly contact the common electrode CE. The second via layer VIA2 may have the same height as the plurality of light emitting elements LE. For example, the second via layer VIA2 may not have a level difference from the plurality of light emitting elements LE. The second via layer VIA2 may be entirely disposed in the display area DA of the substrate 110.

The second via layer VIA2 may include the same material as the first via layer VIA1. For example, the second via layer VIA2 may be made of polyacrylates resin, epoxy resin, phenolic resin, polyamides resin, polyimides rein, unsaturated polyester resin, poly phenylenethers resin, polyphenylenesulfides resin, or benzocyclobutene (BCB).

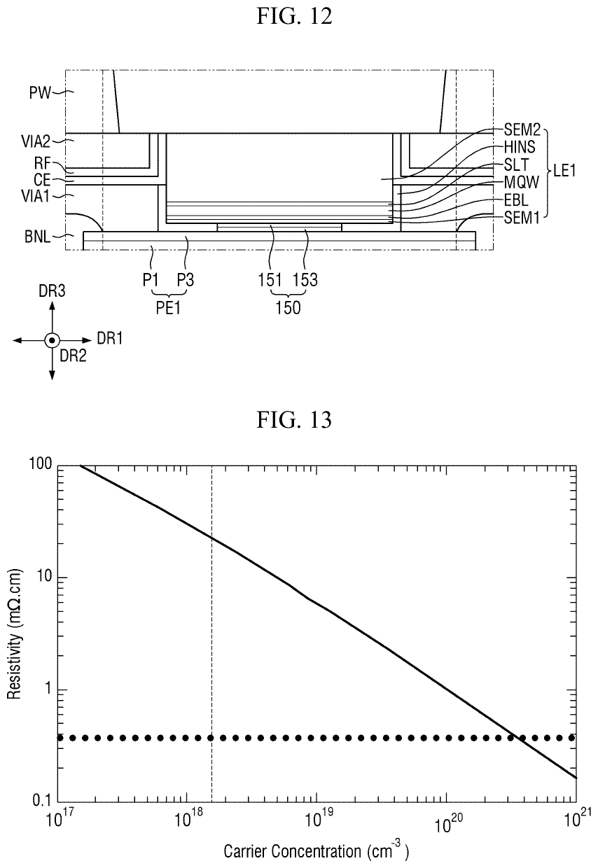

FIG. 13 is a graph illustrating resistance values according to carrier concentration in a light emitting element according to one embodiment.

Referring to FIG. 13, the third semiconductor layer is an undoped semiconductor, but during initial growth on the substrate, high temperatures may cause point defects to form, resulting in an unintentional small amount of doping. Therefore, the third semiconductor layer is sometimes referred to u-GaN (Unintentionally doped-GaN). The carrier concentration in u-GaN is about 10¹⁶ or less.

On the other hand, the second semiconductor layer may be, for example, n-GaN doped with n-type Si, and the carrier concentration of the second semiconductor layer is about 10¹⁸⁻¹⁹ or more.

As can be seen with reference to FIG. 13, the carrier concentration of the third semiconductor layer and the second semiconductor layer differs by about 100 to 1000 times, and therefore, the resistance also differs accordingly. For example, the resistance of the third semiconductor layer may increase by about 10 times or more compared to the resistance of the second semiconductor layer. Accordingly, although the concavo-convex structure of the third semiconductor layer is advantageous for light extraction efficiency, the high resistance of the third semiconductor layer may cause the light emitting element to be unlit or weak in case that the common electrode is formed on the third semiconductor layer.

The display device according to one embodiment does not dispose the common electrode only on the third semiconductor layer, but directly contacts the common electrode with the second semiconductor layer, thereby reducing the contact resistance and improving the case where the light emitting element is not lit or weakly lit.

Hereinafter, a manufacturing process of the display device 10 according to one embodiment will be described with reference to other drawings.

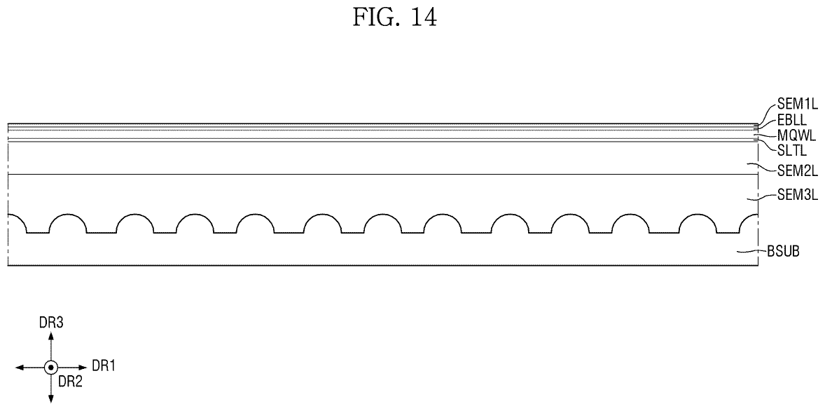

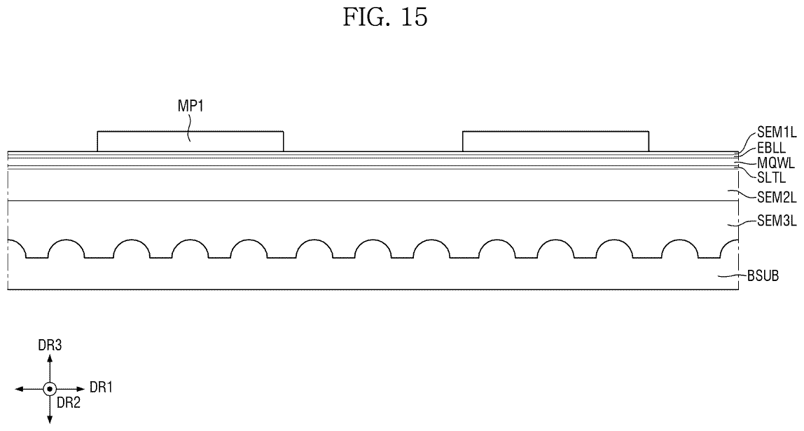

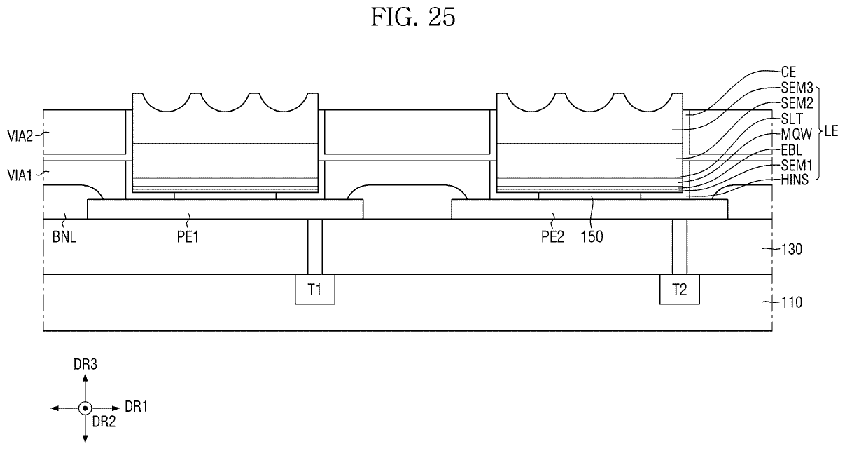

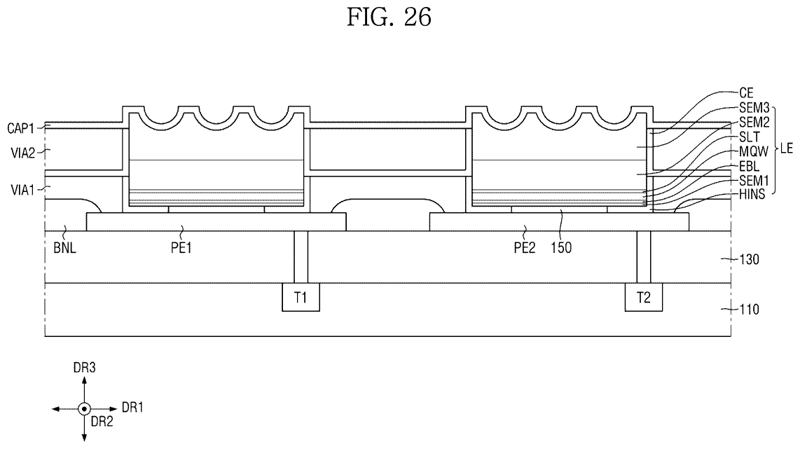

FIGS. 14 to 26 are diagrams for illustrating a method of manufacturing a display device according to one embodiment.

FIGS. 14 to 26 each illustrate a schematic cross-sectional view of the structure of each layer of the display device 10 in the order of formation. FIGS. 14 to 26 mainly show the manufacturing process of the light emitting element unit LEP, and these may generally correspond to the schematic cross-sectional views of FIGS. 6 and 7, respectively. The following will focus on the first emitting area EA1 and the second emitting area EA2 of the display device 10.

Referring to FIGS. 14 to 16, a plurality of light emitting elements LE are formed on the base substrate BSUB.

For example, the base substrate BSUB is prepared as shown in FIG. 14. The base substrate BSUB may be a sapphire substrate Al₂O₃ with irregularities or a silicon wafer containing silicon. For example, the base substrate BSUB may be a Patterned Sapphire substrate (PSS) but is not limited thereto.

A plurality of semiconductor material layers SEM3L, SEM2L, SLTL, MQML, EBLL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like, and, for example, formed by metal organic chemical vapor deposition (MOCVD). However, it is not limited thereto.

A precursor material for forming the plurality of semiconductor material layers is not particularly limited within the range that may be selected for forming the subject material. In one example, the precursor material may be a metal precursor including an alkyl group such as a methyl or ethyl group. For example, it may be a compound such as trimethyl gallium (Ga(CH₃)₃), trimethyl aluminum (Al(CH₃)₃), tricthyl phosphate ((C₂H₅)₃PO₄) but are not limited thereto.

For example, a third semiconductor material layer SEM3L is formed on the base substrate BSUB. While the drawings illustrate the third semiconductor material layer SEM3L being further stacked, it is not limited to this, and a plurality of layers may be formed. The third semiconductor material layer SEM3L may be disposed on the concavo-convex structure of the base substrate BSUB. Accordingly, concavo-convex are also formed on one surface (or a surface) of the third semiconductor material layer SEM3L in contact with the concavo-convex structure of the base substrate BSUB. The concavo-convex of the third semiconductor material layer SEM3L correspond to the concavo-convex of the base substrate BSUB. For example, upwardly concavo-convex are formed on one surface (or a surface) of the third semiconductor material layer SEM3L in contact with the upwardly concavo-convex of the base substrate BSUB. The concavo-convex may be one of a hemisphere shape, a cone shape, a truncated cone shape, a pyramid shape, a truncated pyramid shape, and a cylinder shape but are not limited thereto.

The third semiconductor material layer SEM3L may be disposed to reduce a lattice constant difference between a second semiconductor material layer SEM2L and the base substrate BSUB. For example, the third semiconductor material layer SEM3L may include an undoped semiconductor, which may be an n-type or p-type undoped material. In an embodiment, the third semiconductor material layer SEM3L may be at least one of undoped InAlGaN, GaN, AlGaN, InGaN, AlN, and InN but is not limited thereto.

Using the above-described method, the second semiconductor material layer SEM2L, a superlattice material layer SLTL, an active material layer MQWL, an electron blocking material layer EBLL, and a first semiconductor material layer SEM1L are sequentially formed on the third semiconductor material layer (SEM3L).

A plurality of semiconductor material layers (SEM3L, SEM2L, SLTL, MQML, EBLL, and SEM1L) are etched to form a plurality of light emitting elements LE.

For example, a plurality of first mask patterns MP1 are formed on the first semiconductor material layer SEM1L. The first mask pattern MP1 may be a hard mask containing an inorganic material or a photoresist mask containing an organic material. The first mask pattern MP1 prevents the lower semiconductor material layers (SEM3L, SEM2L, SLTL, MQML, EBLL, and SEM1L) from being etched. A portion of the plurality of semiconductor material layers is etched using the plurality of first mask patterns MP1 as a mask to form the plurality of light emitting elements LE.

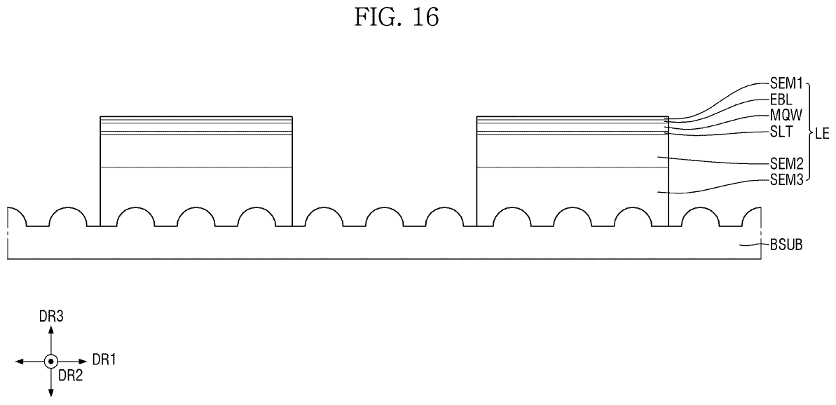

As shown in FIG. 16, on the base substrate BSUB, the plurality of semiconductor material layers SEM3L, SEM2L, MQML, and SEM1L that are non-overlapping the first mask pattern MP1 are etched and removed, and a portion that is not etched overlapping the first mask pattern MP1 may be formed as the plurality of light emitting elements LE.

The semiconductor material layers may be etched by various methods. For example, processes for etching semiconductor material layers may be dry etching, wet etching, reactive ion etching (RIE), deep reactive ion etching (DRIE), inductively coupled plasma reactive ion etching (ICP-RIE), and the like within the spirit and scope of the disclosure. In the case of dry etching, anisotropic etching is possible and may be suitable for vertical etching. In case that using the etching method described above, the etching etchant may be Cl₂ or O₂. However, it is not limited to this.

The plurality of semiconductor material layers (SEM3L, SEM2L, SLTL, MQML, EBLL, and SEM1L) overlapping the first mask pattern MP1 are not etched but formed into the plurality of light emitting elements LE. Accordingly, the plurality of light emitting elements LE are formed including the third semiconductor layer SEM3, the second semiconductor layer SEM2, the superlattice layer SLT, the active layer MQW, the electron blocking layer EBL, and the first semiconductor layer SEM1.

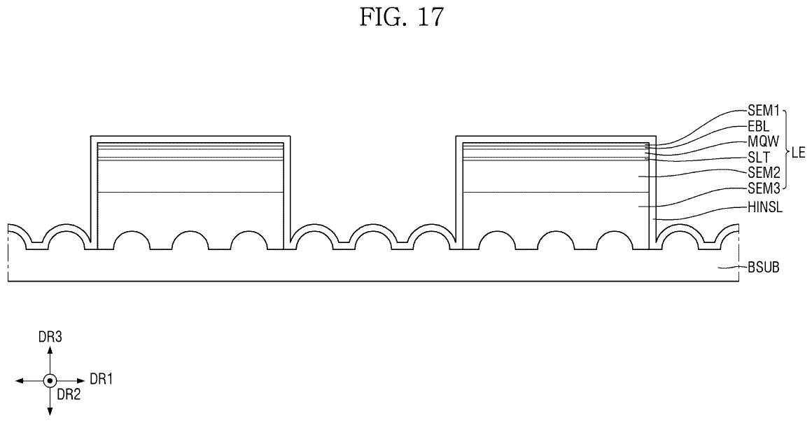

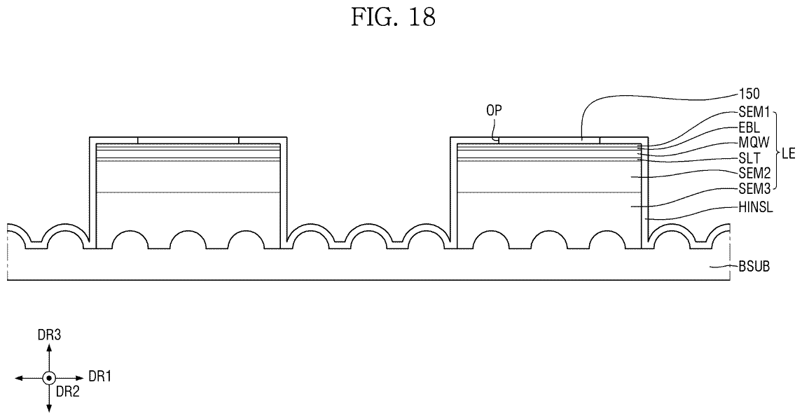

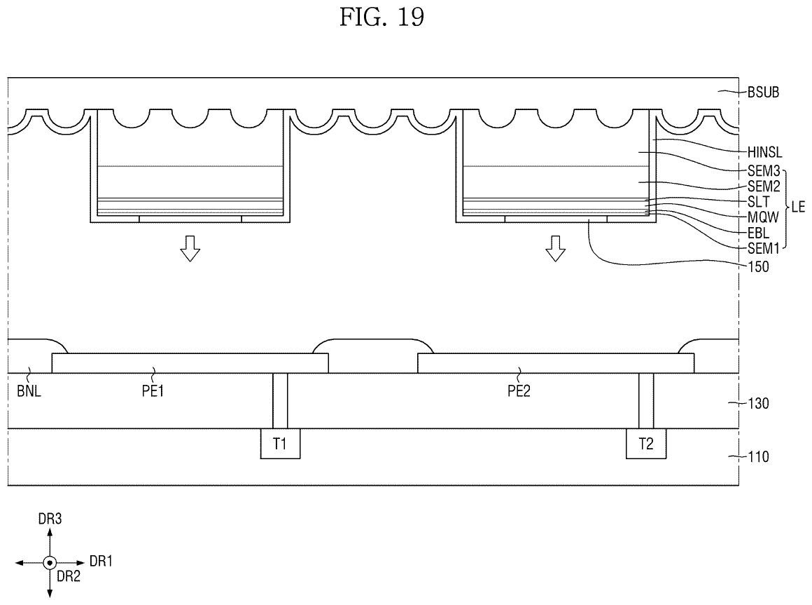

Referring to FIGS. 17 and 18, the heterogeneous insulating layer HINS and the connection electrode 150 are formed on the base substrate BSUB on which the light emitting element LE is formed.

For example, referring to FIG. 17, a heterogeneous insulating material layer HINSL is formed on the outer surface of the plurality of light emitting elements LE. The heterogeneous insulating material layer HINSL may be formed on the front surface of the base substrate BSUB and may be formed not only on the light emitting element LE but also on the top surface of the base substrate BSUB exposed by the light emitting element LE.

For example, the heterogeneous insulating material layer HINSL forms a first insulating material layer having a first refractive index on the front surface of the base substrate BSUB and a second insulating material layer having a second refractive index on the first insulating material layer on the front surface of the base substrate BSUB. Here, the second refractive index is greater than the first refractive index, and the difference between the second refractive index and the first refractive index is about 0.4 or more.

A second etch (2^{nd} etch) is performed to partially remove the heterogeneous insulating material layer HINSL to have an opening OP on the top surface of the light emitting element LE.

For example, in this process, at least a portion of the top surface of the first semiconductor layer SEM1 of the light emitting element LE may be exposed in the heterogeneous insulating material layer HINSL through the opening OP.

The process of partially removing the heterogeneous insulating material layer HINSL may be performed by a process such as anisotropic etching, dry etching, or etchback.

The connection electrode 150 is formed on the first semiconductor layer SEM1 exposed by the opening OP of the light emitting element LE. In one embodiment, the connection electrode 150 may be formed to be flush with the top surface of the light emitting element LE or to protrude beyond the top surface of the light emitting element LE.

The connection electrode 150 may be formed on the first semiconductor layer SEM1 by stacking an electrode material layer on the base substrate BSUB and etching it through an etching process to form the connection electrode 150 on the first semiconductor layer SEM1 but is not limited to. Although not shown, the connection electrode 150 may include a reflective layer and a connection layer.

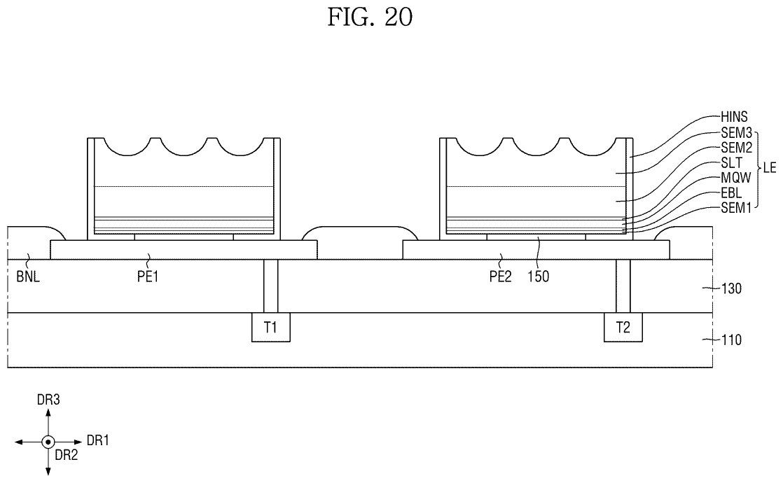

Referring to FIGS. 19 and 20, the plurality of light emitting elements LE of the base substrate BSUB manufactured in FIG. 18 are bonded on the substrate 110 and the plurality of light emitting elements LE are bonded to the first-and second-pixel electrodes PE1 and PE2, and the base substrate BSUB is separated from the plurality of light emitting elements LE.

For example, the base substrate BSUB is aligned on the substrate 110. At this time, the connection electrode 150 of the light emitting element LE formed on the base substrate BSUB is aligned to face the substrate 110. The substrate 110 may have a plurality of pixel electrodes PE1 and PE2 and the bank layer BNL formed thereon as shown in FIG. 6.

The substrate 110 and the base substrate BSUB are bonded. For example, the connection electrode 150 of the light emitting element LE formed on the base substrate BSUB is contacted to the pixel electrodes PE1 and PE2 of the substrate 110. The connection electrode 150 of the light emitting element LE and the pixel electrodes PE1 and PE2 are melt-bonded to bond the substrate 110 and the base substrate BSUB. At this time, the plurality of light emitting elements LE are attached to the top surfaces of the pixel electrodes PE1 and PE2.

Melt bonding may be performed by irradiating a laser to the connection electrodes 150 from the top of the base substrate BSUB. The laser-irradiated connection electrodes 150 may conduct high heat from the laser to bond the interfaces of the connection electrodes 150 of the light emitting element LE and the pixel electrodes PE1 and PE2. For example, the pixel electrodes PE1 and PE2 may include copper (Cu), which has excellent thermal conductivity, and may have excellent adhesion properties with the connection electrode 150 of the light emitting element LE. As a source of the laser used for the fusion bonding, a YAG may be utilized.

The base substrate BSUB is irradiated with a first laser to separate the plurality of light emitting elements LE from the base substrate BSUB. The base substrate BSUB is separated from each third semiconductor layer SEM3 of the plurality of light emitting elements LE.

The process for separating the base substrate BSUB may be separated by a laser lift-off (LLO) process. The laser lift-off process utilizes a laser, and a KrF excimer laser (248 nm wavelength) may be used as the source. The energy density of the excimer laser is irradiated in the range of about 550 mJ/cm² to about 950 mJ/cm², and the incident area may be in the range of about 50×50 μm² to about 1×1 cm² but is not limited thereto. The base substrate BSUB may be separated from the plurality of light emitting elements LE by irradiating the base substrate BSUB with the laser.

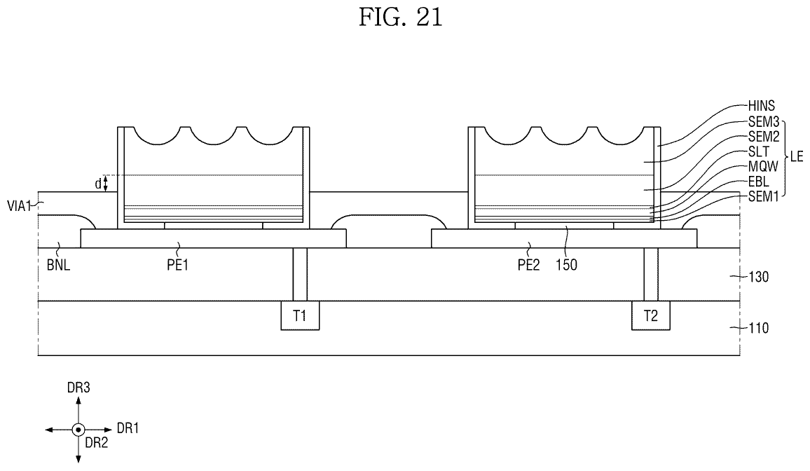

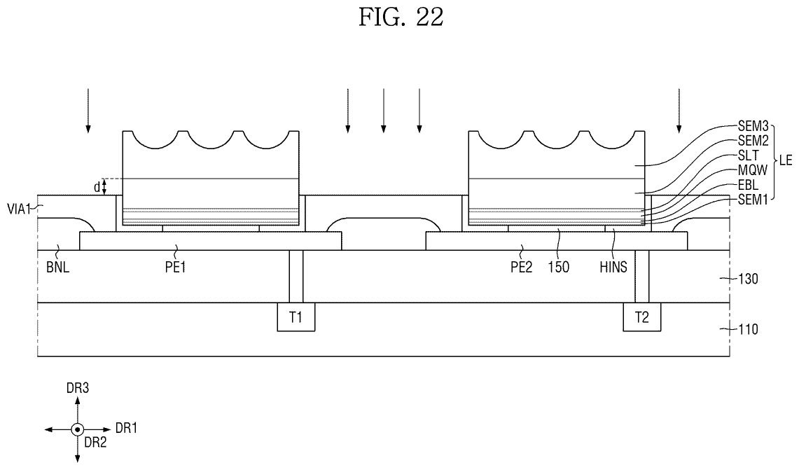

Referring to FIGS. 21 and 22, the first via layer VIA1 is formed, and the heterogeneous insulating layer HINS disposed outside the first via layer VIA1 is removed.

For example, the first via layer VIA1 may be formed on the base substrate BSUB on which the light emitting element LE is not disposed and may be formed to surround the light emitting element LE on the heterogeneous insulating layer HINS. The first via layer VIA1 may be formed by being applied using a solution process such as spin coating or inkjet printing and patterned through an exposure process. The first via layer VIA1 may be formed to a height higher than the height of the active layer MQW of the light emitting element LE. The first via layer VIA1 may be formed to a height lower than the height of the second semiconductor layer SEM2. The respective heights of the first via layer VIA1, the active layer MQW, and the second semiconductor layer SEM2 may be a distance in the third direction DR3, which is the thickness direction, from the second planarization layer 130. The step difference d between the first via layer VIA1 and the second semiconductor layer SEM2 may be 20 nm or more.

The heterogeneous insulating layer HINS may be etched using the first via layer VIA1 as a mask. The heterogeneous insulating layer HINS may be etched using, for example, a wet etching process but is not limited thereto. Accordingly, the step difference d between the heterogeneous insulating layer HINS and the second semiconductor layer SEM2 may be 20 nm or more.

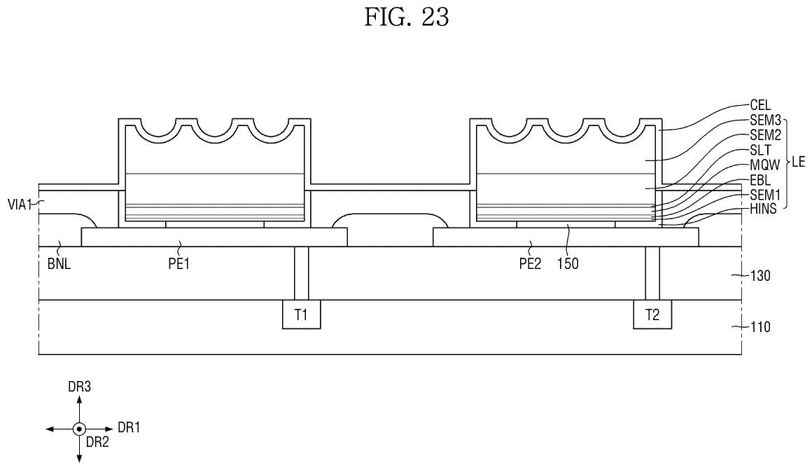

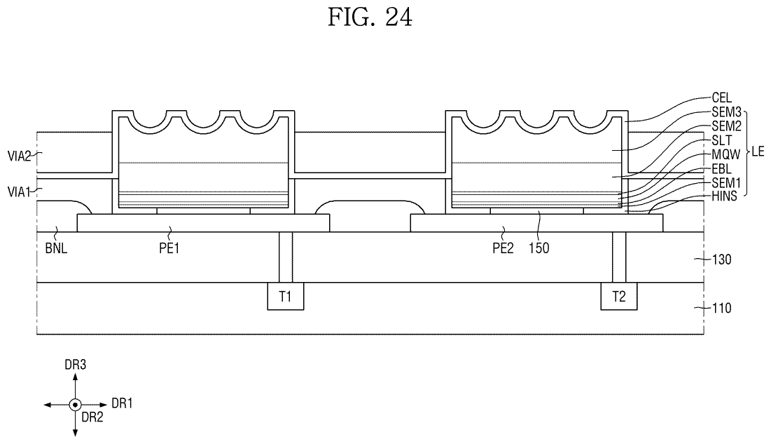

Referring to FIGS. 23 and 24, the common electrode CE and the second via layer VIA2 are formed in contact with the second semiconductor layer SEM2 of the light emitting element EL.

For example, as shown in FIG. 23, a common electrode layer CEL is formed on the substrate 110.

The common electrode layer CEL covers the light emitting element LE and the first via layer VIA1 and may be formed in direct contact with them. The common electrode layer CEL may be continuously formed throughout the display area. The common electrode layer CEL is formed along the top and side surfaces of the third semiconductor SEM3 of the light emitting element LE. The common electrode layer CEL extends from the side of the third semiconductor SEM3 and extends to the side of the second semiconductor SEM2 exposed by the first via layer VIA1. The common electrode layer CEL may include one or more of metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni).

The second via layer VIA2 may be formed on the base substrate BSUB on which the light emitting element LE is not disposed, and the common electrode layer CEL may be formed to surround the light emitting element LE. The second via layer VIA2 may be formed by being applied using the solution process such as spin coating or inkjet printing and patterned through the exposure process. The second via layer VIA2 may be formed at a height equal to or lower than the height of the third semiconductor layer of the light emitting element LE.

The common electrode layer CEL may be etched using the second via layer VIA2 as a mask to form the common electrode CE. Accordingly, the common electrode layer CEL formed on the third semiconductor layer SEM3 may be removed. The common electrode CE is formed on the side surfaces of the third semiconductor layer SEM3 and the second semiconductor layer SEM2 and may extend to the top surface of the first via layer VIA1.

The common electrode CE and the heterogeneous insulating layer HINS may be formed to be aligned with the side of the light emitting element LE.

As shown in FIG. 6, the display device 10 according to one embodiment is manufactured by forming the first capping layer, the partition wall, the wavelength control layer, the color filter layer, and the like within the spirit and scope of the disclosure.

However, the aspects of the disclosure are not restricted to the ones set forth herein. The above and other aspects of the disclosure will become more apparent to one of ordinary skill in the art to which the disclosure pertains by referencing the claims, with functional equivalents thereof to be included therein.

What is claimed is:

1. A display device comprising:
a pixel electrode disposed on a substrate;
light emitting elements disposed on the pixel electrode, the light emitting elements including a first semiconductor layer, an active layer, a second semiconductor layer, and a third semiconductor layer;
a first via layer disposed on the substrate, and having a higher height than a height of the active layer and having a lower height than a height of the third semiconductor layer; and
a common electrode disposed on the first via layer and surrounding side surfaces of the light emitting elements,
wherein the light emitting elements include two or more heterogeneous insulating layers having different refractive indices, and the heterogeneous insulating layers surround top and side surfaces of the first semiconductor layer and further surround at least a portion of a side surface of the second semiconductor layer.

2. The display device of claim 1, wherein
the heterogeneous insulating layers include a first insulating layer having a first refractive index and a second insulating layer having a second refractive index and disposed farther from the active layer than the first insulating layer, and
the first refractive index is less than the second refractive index.

3. The display device of claim 2, wherein a difference between the first refractive index and the second refractive index is about 0.4 or more.

4. The display device of claim 3, wherein a bandgap of the heterogeneous insulating layers is about 3.4 or more.

5. The display device of claim 3, wherein a height of the second semiconductor layer surrounded by the common electrode is about 20 nm or more.

6. The display device of claim 2, wherein a height of the heterogeneous insulating layers and the first via layer is the same.

7. The display device of claim 2, wherein a height of the common electrode and a height of the second via layer are equal.

8. The display device of claim 2, wherein
the heterogeneous insulating layers have an opening exposing a surface of the first semiconductor layer, and
the light emitting elements further include a connection electrode disposed on a surface of the first semiconductor layer exposed by the opening.

9. The display device of claim 2, wherein the third semiconductor layer has a substantially concave-convex structure.

10. The display device of claim 9, wherein the common electrode includes a high reflectivity conductive metal.

11. The display device of claim 10, further comprising:
a capping layer covering a top surface of the third semiconductor layer and a top surface of the second via layer,
wherein the capping layer directly contacts the top surface of the third semiconductor layer.

12. The display device of claim 9, further comprising:
a reflective layer surrounding a side of the light emitting elements on the common electrode.

13. The display device of claim 2, further comprising:
a bank layer disposed on the substrate and dividing a light emitting area and a non- emitting area.

14. The display device of claim 13, further comprising:
partition walls disposed on the common electrode and overlapping the bank layer;
a wavelength conversion layer disposed between the partition walls; and
a color filter layer disposed on the wavelength conversion layer.

15. A display device comprising:
a pixel electrode disposed on a substrate;
light emitting elements disposed on the pixel electrode, the light emitting elements including a first semiconductor layer, an active layer, and a second semiconductor layer;
a first via layer disposed on the substrate and disposed lower than a height of the second semiconductor layer; and
a common electrode disposed on the first via layer and surrounding a side of the second semiconductor layer of the light emitting elements,
wherein the light emitting elements include two or more heterogeneous insulating layers having different refractive indices, and the heterogeneous insulating layers surround top and side surfaces of the first semiconductor layer and side surfaces of the first semiconductor layer and further surround at least a portion of a side surface of the second semiconductor layer.

16. The display device of claim 15, wherein
the heterogeneous insulating layers include a first insulating layer having a first refractive index and a second insulating layer having a second refractive index and disposed farther from the active layer than the first insulating layer, and
the first refractive index is less than the second refractive index.

17. The display device of claim 16, wherein a difference between the first refractive index and the second refractive index is about 0.4 or more.

18. The display device of claim 17, wherein a bandgap of the heterogeneous insulating layers is about 3.4 or more.

19. The display device of claim 17, wherein
a height of the heterogeneous insulating layers and a height of the first via layer are the same, and
a height of the common electrode and a height of the second via layer and a height of the second via layer are the same.

20. The display device of claim 16, wherein
the heterogeneous insulating layers have an opening exposing a surface of the first semiconductor layer, and
the light emitting elements further include a connection electrode disposed on a surface of the first semiconductor layer exposed by the opening.
